(19) United States
(12) Patent Application Publication
(10) Pub. No.: US 2010/0096695 A1
(43) Pub. Date: Apr. 22, 2010

(54) HIGH STRESS FILM

(75) Inventors: Han Guan Chew, Singapore (SG); Jinping Liu, Singapore (SG); Alex Kh See, Singapore (SG); Mei Sheng Zhou, Singapore (SG)

Correspondence Address: HORIZON IP PTE LTD, 7500A Beach Road, #04-306/308 The Plaza, SINGAPORE 199591, SG

(73) Assignee: CHARTERED SEMICONDUCTOR MANUFACTURING, LTD., Singapore (SG)

(21) Appl. No.: 12/252,368

(22) Filed: Oct. 16, 2008

(51) Int. Cl. H01L 47/00; H01L 21/336

(52) U.S. Cl. 257/336; 438/290; 257/E47.001; 257/E21.409

(57) ABSTRACT

A semiconductor device that includes a substrate having an active region prepared with a transistor is presented. The semiconductor device includes a stress structure adjacent to the substrate. The stress structure includes a dielectric layer having nanocrystals embedded therein. The nanocrystals induce a first or a second stress on a channel region of the transistor which improves carrier mobility of the transistor.

### BACKGROUND

Integrated circuits (ICs) semiconductor devices typically comprise numerous circuits components interconnected to perform the desired functions. Such circuit components include, for example, transistors. Dielectric materials have been employed to generate strain in the channel region of the transistor to enhance carrier mobility. For example, tensile stress may be applied to the channel region of n-type transistors to enhance carrier mobility. In the case of p-type transistors, compressive stress may be applied to the channel region.

It is desirable to provide enhanced strain generation in channel regions of transistors to enhance carrier mobility.

### SUMMARY

A semiconductor device is presented in one embodiment. The semiconductor device includes a substrate having an active region prepared with a transistor. A stress structure is disposed adjacent to the substrate. The stress structure includes a dielectric layer having nanocrystals embedded therein. The nanocrystals induce a first or a second stress on a channel region of the transistor which improves carrier mobility of the transistor.

In another embodiment, a method of forming a semiconductor device is disclosed. The method includes providing a substrate having an active region prepared with a transistor and forming a stress structure adjacent to the substrate. The stress structure includes a dielectric layer having nanocrystals embedded therein. The nanocrystals induce a first or a second stress on a channel region of the transistor which improves carrier mobility of the transistor.

A method of forming an integrated circuit is presented in another embodiment. The method includes providing a substrate having an active region prepared with a transistor. The transistor includes a gate stack, source/drain diffusion regions adjacent to the gate stack and a channel in the substrate beneath the gate stack and between the source/drain diffusion regions. The method further includes forming a stress structure adjacent to the substrate. The stress structure includes a dielectric layer having nanocrystals embedded therein. The nanocrystals induce a first or a second stress on the channel region of the transistor which improves carrier mobility of the transistor.

These and other objects, along with advantages and feature of the present invention herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention will now be described hereinafter, by way of example only with reference to the accompanying drawings, in which:

FIG. 1 shows a cross-sectional view of an embodiment of a portion of a device;

FIG. 2 shows a cross-sectional view of another embodiment of a portion of a device;

FIGS. 3a-b show planar and cross-sectional views of yet another embodiment of a portion of a device; and

FIGS. 4-5 plot stress characteristics of stress layers versus temperature.

### DETAILED DESCRIPTION

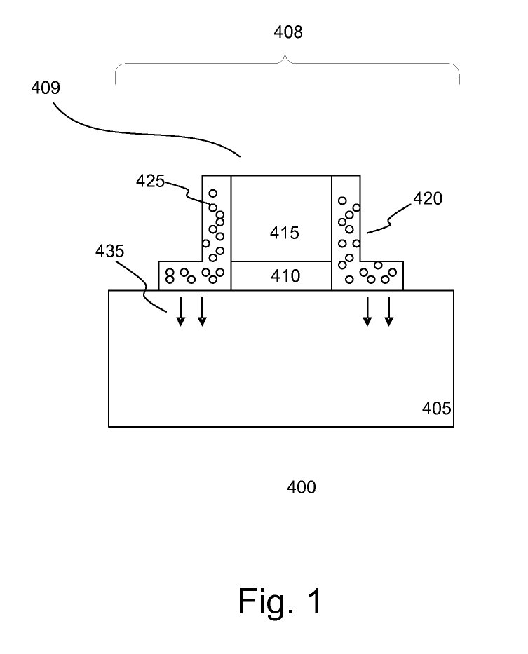

FIG. 1 shows a cross-sectional view of an embodiment of a portion of a device 400. The device includes a substrate 405. The substrate comprises a semiconductor substrate, such as silicon. The substrate may be a lightly doped p-type substrate. Providing other types of substrates, such as silicon-on-insulator, is also useful. An active region 408 is defined on the substrate. The active region, for example, may include a doped well with dopants of a first polarity type. For example, the first polarity type may be p-type, which forms a p-well for a second type (n-type) transistor. In other embodiments, the doped well may have n-type dopants for a p-type transistor. Ion implantation techniques, such as implantation with a mask, can be used to form the doped well. Other techniques for forming the active regions, such as diffusion, are also useful.

Isolating the active region from other active device regions are isolation regions (not shown), such as shallow trench isolation (STI) regions. Various processes can be employed to form the STI regions. For example, the substrate can be etched using etch and mask techniques to form trenches which are filled with a dielectric material such as a high aspect ratio process (HARP) dielectric material. Other types of dielectric materials such as silicon oxide are also useful. Chemical mechanical polishing (CMP) can be performed to remove excess oxide and provide a planar substrate top surface. The STI regions can be formed, for example, prior to or after the formation of the doped wells. Other processes or materials can also be used to form the STIs.

A transistor 409 is disposed in the active region. The transistor includes a gate stack with source/drain regions (not shown) adjacent to the gate. The gate stack may include a gate dielectric layer 410 on the substrate and a gate electrode layer 415 thereover. The gate dielectric layer, for example, may be silicon oxide while the gate electrode layer may be polysilicon. Other types of gate dielectric and electrode materials are also useful.

To form the gate stack, various layers of the gate stack are deposited on the substrate. For example, gate dielectric, gate electrode and etch stop layers can be formed on the substrate. The layers are patterned using, for example, mask and etch processes, leaving the gate stack in the active region. During subsequent processing, the etch stop layer is removed from the gate stack.

Source/drain diffusion regions can be formed by ion implantation in the substrate adjacent to the gate stack. For p-type transistors, p-type dopants are implanted. Metal silicide contacts may be formed in the source/drain regions and the top of the gate electrode layer. Various types of metal silicides, such as nickel or nickel alloy, can be employed.

In one embodiment, stress spacers 420 are provided on sidewalls of the gate stack. The stress spacers, as shown, comprise L-shaped stress spacers. Other shaped stress spacers are also useful. For example, the stress spacers can include L-shaped offset spacer liners and stress spacers thereon. Alternatively, the stress spacers include stress offset spacer liners with non-stressed spacers. In other embodiment, the stress spacers can include stress L-shaped offset spacers with stress spacers over it. Other configurations of stress spacers are also useful.

The stress spacers can be formed when source/drain diffusion regions are formed in the process flow of forming a transistor. For example, source/drain extensions are formed prior to forming the stress spacers while source/drain diffusion regions are formed afterwards. As such, the stress spacers can be easily implemented in the process flow without additional masks.

In one embodiment, the stress spacers comprise a dielectric material. The dielectric material may be, for example, silicon oxide, high-k dielectric materials such as HfAlO or HfSiON. Other types of dielectric materials, such as nitride or HARP, are also useful. The dielectric material is doped with nanocrystals 425 to produce a stress dielectric material. For example, nanocrystals are embedded in the dielectric material. Dopant nanocrystals, in one embodiment, comprise germanium (Ge). The dielectric material can also be doped with other types of nanocrystals or a combination of different types of nanocrystals. In one embodiment, the stress dielectric material comprise about 4 to 8 at % nanocrystals.

Various techniques may be used to form the stress dielectric material. In one embodiment, a dielectric layer can be formed on the substrate. Chemical vapor deposition (CVD) can be used to form the dielectric layer. Other types of processes are also useful to form the dielectric layer. Dopants can be embedded into the dielectric layer by ion implantation to form a stress layer. Alternatively, dopants can be embedded into the dielectric layer using an insitu process to form the stress layer. The insitu process can be chemical or physical. For example, a dielectric layer can be formed by CVD or rapid thermal annealing (RTA) with germanium hydride (GeH₄) precursors or co-sputtering using Ge and SiO₂ target. Other techniques for forming the stress layer are also useful. The stress layer can be patterned to form the stress spacers. The thickness of the stress layer, for example, may be about 100 Å. Other thicknesses may also be useful.

The various process parameters of doping the stress spacer material affect the magnitude of stress in the stress spacers. The stress applies a force 435 on the substrate. The force affects mobility and velocity of charge carriers of the transistor, changing the efficiency of the device. The process parameters of doping the stress spacers can be adjusted to cause the nanocrystals to vary in size, quality and distributions to achieve the desired stress and effect on charge carriers of the transistor. In one embodiment, the stress spacers apply a compressive stress on the substrate. This results in a tensile stress applied on a channel of the transistor between the source/drain regions. The magnitude of the stress may be from about several hundred MPa to a few GPa. The tensile stress on the channel, for example, improves carrier mobility and velocity of n-type transistors. In alternative embodiments, the stress layer may apply other stress types or stress magnitudes.

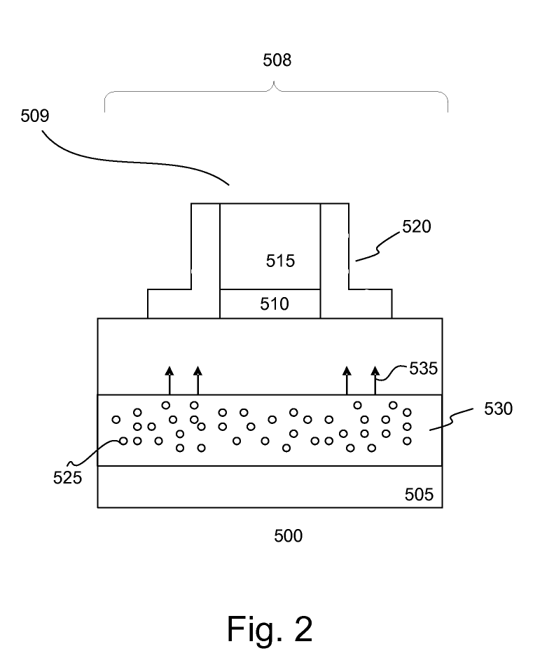

FIG. 2 shows a cross-sectional view of another embodiment of a portion of a device 500. The device includes a substrate 505. The substrate comprises a semiconductor substrate, such as silicon. The substrate may be a lightly doped p-type substrate. In one embodiment, the substrate comprises a silicon-on-insulator (SOI) substrate. The SOI substrate comprises a buried dielectric layer 530 beneath the surface of the substrate. The buried dielectric layer may be SiO₂. Other types of buried dielectric layers are also useful. The buried dielectric layer is about 1400 Å thick and at least about 100 Å below the surface of the substrate. Providing a buried dielectric layer at other depths or with other thicknesses is also useful. The SOI can be formed by, for example, providing a bulk substrate with an oxide layer thereon and bonding another silicon substrate. Other techniques for providing an SOI substrate are also useful.

An active region 508 is defined on the substrate. The active region, for example, may include a doped well with dopants of a first polarity type. In one embodiment, the first polarity type comprises p-type. Isolating the active region from other active device regions are isolation regions (not shown), such as shallow trench isolation (STI) regions.

A transistor 509 is disposed in the active region. The transistor includes a gate stack with source/drain regions (not shown) adjacent to the gate. The gate stack may include a gate dielectric layer 510 on the substrate and a gate electrode layer 515 thereover. The gate dielectric layer, for example, may be silicon oxide while the gate electrode layer may be polysilicon. Other types of gate dielectric and electrode materials are also useful.

Source/drain diffusion regions can be formed by ion implantation in the substrate adjacent to the gate stack. For p-type transistors, p-type dopants are implanted. Metal silicide contacts may be formed in the source/drain regions and the top of the gate electrode layer. Various types of metal silicides, such as nickel or nickel alloy silicide, can be employed. Spacers 520 are provided on sidewalls of the substrate. The spacers, as shown, comprise L-shaped stress spacers. Other shaped stress spacers are also useful.

In one embodiment, the buried dielectric layer comprises a stress buried dielectric layer. The stress buried dielectric layer includes dopants to impart stress in the buried dielectric layer. In one embodiment, the stress buried dielectric layer comprises dopant nanocrystals 525 embedded therein. Nanocrystals, such as Ge, are embedded in the stress buried dielectric layer. Providing other types of dopant nanocrystals may also be useful. The stress buried dielectric layer, in one embodiment, comprises about 4-8 at % nanocrystals. Other concentration of dopant nanocrystals may also be used. Various techniques can be used to form the stress buried dielectric layer. For example, similar processes such as those described in forming the stress dielectric material of the stress spacers can be employed.

The various process parameters of doping the buried stress layer affect the magnitude of stress. The stress applies a force 535 on the substrate. The force affects mobility and velocity of charge carriers of the transistor, changing the efficiency of the device. The process parameters of forming the buried stress layer can be adjusted to achieve the desired stress and effect on charge carriers of the transistor. In one embodiment, the buried stress layer applies a compressive stress on the substrate. This results in a tensile stress applied on a channel of the transistor between the source/drain regions. The magnitude of the stress may be from about several hundred MPa to a few GPa. The tensile stress on the channel, for example, improves carrier mobility and velocity of n-type transistors. In alternative embodiments, the stress layer may apply other stress types or stress magnitudes.

In other embodiments, the device can include both stress spacers and buried stress dielectric layer.

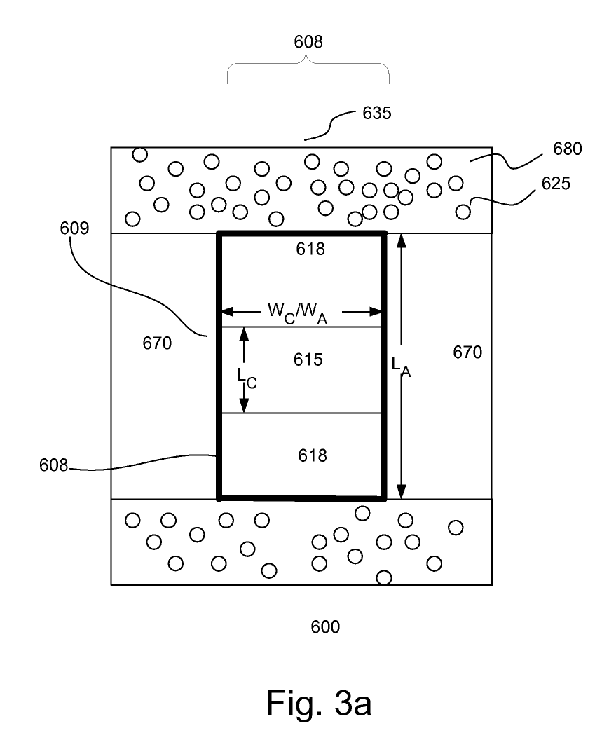

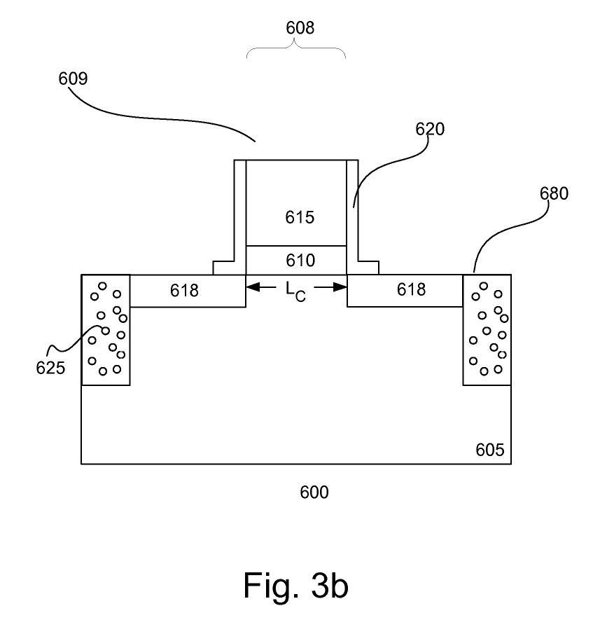

FIGS. 3a-b show planar and cross-sectional views of yet another embodiment of a device 600. The substrate includes a semiconductor substrate 605, such as silicon. The substrate may be a lightly doped p-type substrate. Providing other types of substrates, such as silicon-on-insulator, is also useful. An active region 608 is defined on the substrate. The active region, for example, may include a doped well with dopants of a first polarity type. In one embodiment, the first polarity type comprises n-type dopants to form a n-well on which a second type (p-type) transistor is formed. The active region as shown is rectangular in shape. Providing active regions having other shapes are also useful.

A transistor 609 is disposed in the active region. The transistor includes a gate stack with source/drain regions 618 adjacent to the gate. The gate stack may include a gate dielectric layer 610 on the substrate and a gate electrode layer 615 thereover. The gate dielectric layer, for example, may be silicon oxide while the gate electrode layer may be polysilicon. Other types of gate dielectric and electrode materials are also useful. The source/drain regions comprise second type dopant. In one embodiment, the second type dopant comprises p-type dopants for a p-type transistor. Metal silicide contacts may be formed in the source/drain regions and the top of the gate electrode layer. Various types of metal silicides, such as nickel or nickel alloy silicide, can be employed. Spacers 620 may be provided on sidewalls of the substrate. The spacers, as shown, comprise L-shaped spacers. Other shaped spacers are also useful.

Isolating the active region from other active device regions are isolation regions, such as shallow trench isolation (STI) regions. In one embodiment, the shallow trench isolation comprises first and second sub-regions 670 and 680. The first sub-regions are disposed on opposing sides along length L_{A} of the active region; the second sub-regions are disposed on opposing sides along length W_{A} of the active region. The second sub-regions, for example, overlap the first sub-regions. Providing other configurations of sub-regions, such as having first sub-regions overlapping the second sub-regions or a combination of first and second overlapping sub-regions, are also useful. The depth of the sub-regions may be about 1000 Å. Other depths are also useful. The depth, for example, may depend on the amount of stress required.

In one embodiment, the first and second sub-regions comprise isolation material such as a high aspect ratio process (HARP) dielectric material. Other types of dielectric materials, such as high-k dielectric material, are also useful. The second sub-regions comprise stress isolation sub-regions. The stress isolation region comprises a stress dielectric material. In one embodiment, the stress dielectric material comprises dopant nanocrystals embedded therein. For example, Ge nanocrystals are embedded in the stress dielectric material. Providing other types of dopant nanocrystals can also be useful. The stress dielectric material, in one embodiment, comprise about 4-8 at % nanocrystals. Other concentration of dopant nanocrystals can also be useful.

In one embodiment, the second sub-region is formed after the formation of the first sub-region. Forming the first and second sub-regions simultaneously is also useful. The first and second sub-regions comprise, in one embodiment, HARP materials. Providing first and second sub-regions with different materials may also be useful. A mask can be provided on top of the first and second sub-regions and patterned to expose the second sub-region for selectively embedding the nanocrystals. Various techniques can be used to form the stress dielectric material. For example, similar processes such as those described in forming the stress dielectric material of the stress spacers can be employed.

The various process parameters of doping the stress layer affect the magnitude of stress. The stress applies a force on the substrate. The force affects mobility and velocity of charge carriers of the transistor, changing the efficiency of the device. The process parameters of doping the stress spacers can be adjusted to achieve the desired stress and affect on charge carriers of the transistor. In one embodiment, the stress sub-regions apply a compressive stress in a channel of the transistor between the source/drain regions. The magnitude of the stress may be from about several hundred MPa to a few GPa. The compressive stress on the channel, for example, improves carrier mobility and velocity of p-type transistors. In alternative embodiments, the stress isolation sub-regions layer may apply other stress types or stress magnitudes.

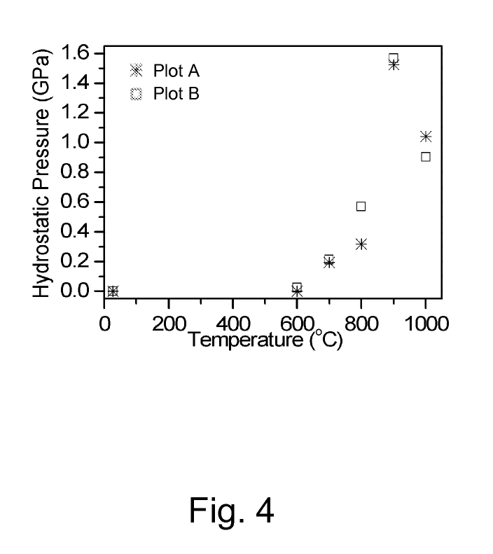

FIG. 4 plots hydrostatic pressure versus temperature of two layers embedded with nanocrystals. The stress layers comprise silicon oxide with about 4% Ge nanocrystals. The thickness of the stress layer is about 3000 Å and the size of the nanocrystal is about 1-20 nm. Plot A measures the hydrostatic pressure of films annealed at different temperatures for 15 minutes while Plot B measures the hydrostatic pressure of films annealed at different temperatures for 50 minutes. As indicated by FIG. 4, it appears that in general higher annealing temperature and/or longer annealing time can increase hydrostatic pressure in the stress layers.

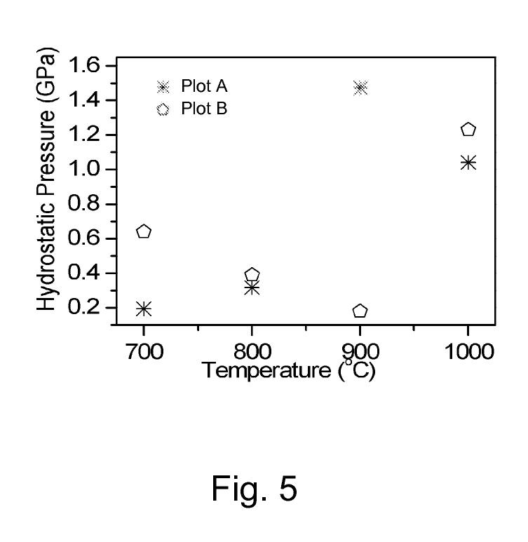

FIG. 5 plots hydrostatic pressure versus temperature of layers embedded with different concentrations of nanocrystals. The thickness of the stress layers is about 3000 Å and the size of the nanocrystal is about 1-20 nm. Plot A measures the hydrostatic pressure of silicon oxide embedded with about 4% Ge nanocrystals while Plot B measures the hydrostatic pressure of silicon oxide with about 10% Ge nanocrystals. As indicated by FIG. 5, it appears that in general higher annealing temperatures and/or higher concentrations of Ge nanocrystals can increase hydrostatic pressure in the stress layers. However, in the case where concentration of Ge nanocrystals is about 10% or greater, faceting of crystals can occur. This can result in the stress being reduced, as indicated by Plot B.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1-12. (canceled)

13. A method of forming a semiconductor device comprising:
providing a substrate having an active region prepared with a transistor; and
forming a stress structure comprising a dielectric layer having nanocrystals embedded therein, wherein the nanocrystals induce a first or a second stress on a channel region of the transistor which improves carrier mobility of the transistor.

14. The method of claim 13 wherein forming the stress structure comprises:
implanting nanocrystals into the dielectric layer using ion implantation;
annealing the dielectric layer with germanium hydride precursors; or
co-sputtering the dielectric layer using germanium and silicon oxide target.

15. The method of claim 14 wherein the nanocrystals comprise Ge nanocrystals.

16. The method of claim 15 wherein the dielectric layer comprises about 4-8 at % of Ge nanocrystals.

17. The method of claim 13 wherein:
the stress structure is disposed on sidewalls of the transistor;
the stress structure is disposed beneath a surface of the substrate; or
the stress structure is disposed on an isolation region along a width of the substrate.

18. The method of claim 13 wherein:
the transistor is a n-type transistor;
the stress structure is disposed on sidewalls of the transistor; and
the nanocrystals apply the first stress having a compressive stress and induce the second stress comprising a tensile stress on the channel of the transistor.

19. The method of claim 13 wherein:
the transistor is a n-type transistor;
the stress structure is disposed beneath a surface of the substrate; and
the nanocrystals apply the first stress having a compressive stress and induce the second stress comprising a tensile stress on the channel of the transistor.

20. The method of claim 13 wherein:
the transistor is a p-type transistor;
the stress structure is disposed on an isolation region along a width of the substrate; and
the nanocrystals apply the first stress having a compressive stress and induce the first stress on the channel of the transistor.

21. A method of forming a semiconductor device comprising:
providing a substrate having an active region prepared with a transistor, wherein the transistor comprises a gate stack, source/drain diffusion regions adjacent to the gate stack and a channel in the substrate beneath the gate stack and between the source/drain diffusion regions; and
forming a stress structure comprising a dielectric layer having nanocrystals embedded therein, wherein the nanocrystals induce a first or a second stress on the channel region of the transistor which improves carrier mobility of the transistor.

22. The method of claim 21 wherein:
the transistor is a n-type transistor;
the stress structure is disposed on sidewalls of the transistor; and
the nanocrystals apply the first stress having a compressive stress and induce the second stress comprising a tensile stress on the channel of the transistor.

23. The method of claim 21 wherein:
the transistor is a n-type transistor;
the stress structure is disposed beneath a surface of the substrate; and
the nanocrystals apply the first stress having a compressive stress and induce the second stress comprising a tensile stress on the channel of the transistor.

24. The method of claim 21 wherein:
the transistor is a p-type transistor;
the stress structure is disposed on an isolation region along a width of the substrate; and
the nanocrystals apply the first stress having a compressive stress and induce the first stress on the channel of the transistor.

25. The method of claim 21 wherein providing the stress structure comprises:
implanting nanocrystals into the dielectric layer using ion implantation;
annealing the dielectric layer with germanium hydride precursors; or
co-sputtering the dielectric layer using germanium and silicon oxide target.

26. The method of claim 21 wherein the stress structure comprises sidewall spacers, buried dielectric layer or shallow trench isolation regions.

27. The method of claim 21 wherein the dielectric layer comprises silicon oxide, high-k dielectric material, nitride or high aspect ratio process (HARP) dielectric material.

28. A method of forming an integrated circuit comprising:
providing a substrate prepared with a device region and a device structure on the substrate in the device region; and
forming a stress structure comprising a dielectric layer having nanocrystals embedded therein, wherein the nanocrystals induce a first or a second stress on the region includes the substrate beneath the device structure which improves carrier mobility of the device.

29. The method of claim 28 wherein providing the stress structure comprises:
implanting nanocrystals into the dielectric layer using ion implantation;
annealing the dielectric layer with germanium hydride precursors; or
co-sputtering the dielectric layer using germanium and silicon oxide target.

30. The method of claim 29 wherein the nanocrystals comprise Ge nanocrystals.

31. The method of claim 30 wherein the dielectric layer comprises about 4-8 at % of Ge nano crystals.

32. The method of claim 28 wherein:
the stress structure is disposed on sidewalls of the device structure;
the stress structure is disposed beneath a surface of the substrate; or
the stress structure is disposed on an isolation region along a width of the substrate.

33. The method of claim 28 wherein the stress structure comprises sidewall spacers, buried dielectric layer or shallow trench isolation regions.
